(19) United States
(12) Patent Application Publication
(10) Pub. No.: US 2020/0227571 A1
(43) Pub. Date: Jul. 16, 2020

(54) SEMICONDUCTOR SYSTEM INCLUDING A PIN DIODE

(71) Applicant: Robert Bosch GmbH, Stuttgart (DE)

(72) Inventors: Alfred Goerlach, Kusterdingen (DE); Wolfgang Feiler, Reutlingen (DE)

(21) Appl. No.: 16/633,426

(22) PCT Filed: Jun. 11, 2018
(86) PCT No.: PCT/EP2018/065301

§ 371 Date: Jan. 23, 2020

(30) Foreign Application Priority Data
Jul. 24, 2017 (DE) 102017212673.6

(51) Int. Cl. H01L 29/868; H01L 29/06; H01L 29/66; H01L 29/417

(52) U.S. Cl. CPC H01L 29/868; H01L 29/417; H01L 29/66136; H01L 29/0603

(57) ABSTRACT

A semiconductor system includes a PIN diode including a heavily n-doped layer, a lightly n-doped layer situated on the heavily n-doped layer, and a p-doped layer situated on the lightly n-doped layer, the p-doped layer forming an ohmic contact with a first metallization and the heavily n-doped layer forming an ohmic contact with a second metallization. During operation in the forward direction, a high injection takes place in which the lightly n-doped layer is flooded with charge carriers. At least two trench structures are introduced into the lightly n-doped layer, the trench structures on a surface in contact with the n-doped surface including a dielectric layer. The surface of the lightly n-doped layer in contact with the dielectric layer includes an increased surface recombination velocity for charge carriers.

### FIELD OF THE INVENTION

The present invention relates to a semiconductor system including a PIN diode.

### BACKGROUND INFORMATION

In PIN diodes, an approximately undoped or intrinsic layer, in which the voltage drops in case of blocking, is located between the p-doped anode zone and the heavily n-doped cathode area. The intrinsic layer is usually lightly n-doped as a result of manufacturing. During operation in the forward direction, in contrast, electrons and holes are injected into the lightly doped area, whose concentration exceeds the slight doping of the I-layer (high injection), so that the resistance and thus the voltage drop is reduced. The higher the injected charge is, the lower the forward voltage is. In the event of shutdown, for example, in the event of an abrupt current commutation, in contrast, the charge carriers (electrons and holes) which were injected during the operation in the forward direction into the lightly doped area and stored therein firstly have to be dissipated before the high-voltage PIN diode is at all capable of accepting blocking voltage again. Therefore, in the event of an abrupt current commutation, the current firstly continues to flow in the blocking direction until the stored charge carriers are dissipated and/or depleted. This procedure, i.e., the level and the duration of the depletion current for dissipating the stored charge carriers is primarily determined by the quantity of the charge carriers stored in the lightly doped area. A higher and longer-lasting depletion current means a higher shutdown power loss. Therefore, a compromise always has to be made between low forward voltages or bias voltages and low switching losses.

This has resulted in the development of various concepts for rapid, low-loss high-voltage diodes (HV diodes).

In the CAL-Diode (Controlled Axial Lifetime) [J. Lutz, U. Scheuermann, “Advantages of the new Controlled Axial Lifetime Diode,” Power Conversion, June 1994 Proceedings, pp. 163], in addition to the typical homogeneous reduction of the charge carrier lifetimes with the aid of heavy metals such as platinum or electron irradiation, a local increase of the recombination centers in the vicinity of the PN or PI transition is additionally carried out by irradiation using helium ions. The charge carrier profile is thus reduced at the boundary of the high resistance zone to the p-doped area, which enables a soft shutdown (low current change per unit of time).

A similar carrier profile is obtained using the so-called EMCON diodes (Emitter Controlled Diode) [A. Porst, F. Auerbach, H. Brunner, G. Deboy, F. Hille, Improvement of the Diode Characteristics using Emitter-Controlled Principles (EMCON-DIODE),” Power Semiconductor Devices and IC's, 1997. ISPSD '97, 1997]. In addition to a lifetime reduction with the aid of platinum, the anode emitter efficiency is reduced therein by a suitable doping profile of the anode.

Similar advantageous structures which also manage entirely without lifetime influence are structures which form a combination of Schottky and PIN diodes. The trench-merged PIN-Schottky diode (TMPS), which is described in U.S. Pat. No. 9,006,858, is mentioned by way of example.

### SUMMARY OF THE INVENTION

The semiconductor system according to the present invention of a PIN diode having the features of the independent patent claim has the advantage that a particularly simply and cost-effectively manufactured diode is provided, in which the lifetime and accordingly the current in the event of a dynamic shutdown is set very easily. A highly-blocking diode having defined properties may thus be implemented at a reasonable price. The lifetime of the charge carriers may be influenced accordingly by the selection of an appropriately adapted surface recombination velocity on the surface of trench structures and thus in particular the switching or shutdown behavior may be influenced. The level of the shutdown current may be influenced accordingly by selection of the surface recombination velocity. A high-voltage diode having defined losses in the dynamic operating case of the shutdown of the diode may thus be provided. Because of the simple manufacturing process, the diodes are also suitable for PIN diodes made of silicon carbide (SiC).

Further advantages and improvements result by way of the features of the dependent patent claims. An improvement of the shutdown behavior may be achieved in particular if the features of the dependent patent claims are implemented. An improvement of the shutdown behavior may be achieved in particular if the increase of the surface recombination velocity is not formed in the entire boundary surface, but rather only in a portion, which may be in the base of the trenches. Improved switching behavior of the diode may be achieved by this measure, without the forward voltage or the reverse current thus being negatively influenced. The electrical properties of the semiconductor systems may be influenced accordingly by selection of the corresponding geometric dimensions of the trench structures and the distances between the trench structures. The ratio of the width of the trench structures to the distance of the trench structures is advantageously in a range of 0.1 to 10, since a sufficient influence of the increased surface recombination velocity on the distribution of the charge carriers of the PIN diode is thus achieved. The influence of the increased surface recombination velocity on the area flooded with charge carriers in the forward direction may be influenced by selection of the depth of the trench structures in relation to the lightly n-doped layer. If the depth of the trench structure is between 2% and 20% of the thickness of the lightly n-doped layer, a significant effect of the increased surface recombination velocity is thus visible, very high surface recombination velocities still having to be selected in this area. If the depth of the trench structure is between 20% and 98% of the lightly n-doped layer, significant effects on the PIN diode may thus already be implemented using lower surface recombination velocities. This effect acts particularly strongly if the depth of the trench structure exceeds the depth of the lightly n-doped layer and thus the trench structures extend up to the heavily n-doped layer. The trench structures may alternatively either be introduced through the p-doped layer or through the heavily n-doped layer into the lightly n-doped layer. The semiconductor system according to the present invention may be manufactured particularly simply if a heavily doped substrate is used for the heavy n-doping, on which a lightly n-doped layer is produced by epitaxy and the p-doped layer is produced thereon by an implantation in the epitaxy layer. Alternatively, it is also possible to exchange all p and n dopings with one another.

Exemplary embodiments of the present invention are shown in the drawings and explained in greater detail in the following description.

### BRIEF DESCRIPTION OF THE DRAWINGS

FIG. 1 shows a first exemplary embodiment of the diode according to the present invention.

FIG. 2 shows another example of the diode according to the present invention, the trench structures being configured to be deeper.

FIG. 3 shows another exemplary embodiment in which the deeper trench structures exceed the thickness of the lightly n-doped layer.

FIG. 4 shows another exemplary embodiment in which the trench structures are introduced through the heavily n-doped layer.

FIG. 5 shows the distribution of the charge carriers along the depth of the semiconductor system for various exemplary embodiments.

FIG. 6 shows the current during the shutdown of the diode.

### DETAILED DESCRIPTION

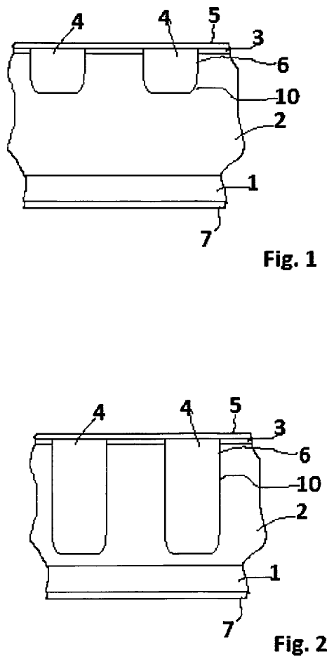

FIG. 1 shows a cross section through a first example of the semiconductor system according to the present invention including a PIN diode. The diode according to the present invention includes a heavily n-doped layer 1 and a lightly n-doped layer 2 situated thereon. Lightly n-doped layer 2 includes a p-doped layer 3 on the upper side. P-doped layer 3 is in contact with a metallization 5, metallization 5 and p-doped layer 3 forming an ohmic contact with one another. A further metallic layer 7 is also situated on the lower side, which forms an ohmic contact with heavily n-doped layer 1. Furthermore, trench structures 4 are provided, which extend on the upper side through p-doped layer 3 into lightly n-doped layer 2. Two trench structures 4 are shown in FIG. 1. Trench structures 4 are filled using a dielectric material 6, for example, silicon oxide. Alternatively, only a superficial dielectric layer in trench structures 4, for example, made of silicon oxide, and a filling of the trenches with other dielectric materials may also be provided.

The manufacturing of such a structure according to FIG. 1 proceeds, for example, from a heavily n-doped semiconductor substrate. A lightly n-doped layer 2 is deposited on the surface of the semiconductor substrate by an epitaxy process. Since a semiconductor substrate typically has a certain thickness, the thickness of heavily n-doped layer 1 shown in FIG. 1 does not correspond to reality. A semiconductor substrate of several hundred micrometers thickness would typically be used, on which an epitaxy layer in the order of magnitude of 35 μm, for example, is deposited. However, since the thickness of heavily n-doped layer 1 is nearly meaningless because of the heavy doping, it was shown having only a very low thickness in FIG. 1. P-doped layer 3 is formed by an implantation process into lightly n-doped layer 2.

For example, for a diode having a blocking voltage of 500 V, a lightly n-doped layer 2 having a thickness of 35 μm and a doping concentration of 10¹⁴/cm³ is used by way of example. P-doped layer 3 has, for example, a thickness of 0.5 μm and has a doping of 10¹⁹/cm³ at the surface. Trench structures 4 typically have a width of approximately 1 μm and are at a distance of approximately 1 μm from one another. Trench structures 4 form long trenches aligned in parallel to one another perpendicular to the plane of the paper of the drawing of FIG. 1. The depth of trench structures 4 is, for example, 2 μm. The base of trench structures 4 may be rounded, for example, having a rounding radius R=0.5 μm.

It is provided according to the present invention that the superficial n-layer which extends up to trench structures 4 is configured as a layer 10 having an increased surface recombination velocity. Such an elevation of the surface recombination velocity may be carried out, for example, after the production of trench structures 4 and before the deposition of silicon oxide 6 by an ion implantation of silicon ions on the trench surface. Crystal defects, which result in an elevation of the surface recombination velocity, are produced in the lightly n-doped material by such an implantation of silicon ions. Alternatively, this elevation of the surface recombination velocity may also be carried out by suitable etching processes, which convert, for example, a very thin superficial layer of lightly n-doped silicon 2 into porous silicon. Alternatively, the surface recombination velocity may also be increased by targeted contamination with heavy metals in the area of the surface of trench structures 4. Due to this increase of the surface recombination velocity, trench structures 4 cause a reduction of the charge carriers in the areas which are situated adjacent to trench structures 4. The switching behavior of the PIN diodes may therefore be influenced accordingly by this measure.

Due to the selected doping concentrations of the p-layer and the n-layer, upon application of a forward voltage, i.e., if a more positive voltage is applied to metallization 5 than to metallization 7 and holes are injected into the n-layer, high injection takes place in lightly n-doped material 2. High injection means that for reasons of charge neutrality, an electron-hole plasma forms, its charge carrier concentration being far above the doping concentration in lightly n-doped area 2. This has the result that the current flow in this lightly n-doped area 2 is not dependent on the doping concentration of lightly n-doped layer 2, but rather on the charge carriers of the plasma which flood this area. Due to such flooding of lightly n-doped area 2, the diode behaves like a normal diode upon current flow in the forward direction, but with a quite small voltage drop.

However, it is characteristic for such diodes that in the event of a voltage reversal, i.e., proceeding from a voltage in the forward direction, an application of a blocking voltage, i.e., a higher positive voltage on metallization 7 in relation to metallization 5, the diode does not immediately display a blocking behavior. Rather, the charge carriers with which lightly n-doped area 2 was flooded initially have to be removed again. This means that upon application of a blocking voltage, a current initially flows for a short period of time until all charge carriers are removed from lightly n-doped area 2. This behavior of the PIN diodes in the blocking direction is influenced by the approach according to the present invention of influencing the surface recombination velocity in the area of the surface of trench structures 4.

By influencing the surface recombination velocity, the lifetime of the charge carriers in the area in the vicinity of trench structures 4, in particular between two trench structures 4, may be lastingly influenced. The higher the surface recombination velocity is set, the higher is the effect on the current flow in the blocking direction. If the surface recombination velocity is selected to be very high, relatively many of the charge carriers are thus already removed through trench structures 4 by recombination, whereby the current flow in the reverse direction is reduced.

A further measure for influencing the current in the blocking direction is explained in greater detail in FIG. 2. A similar structure as in FIG. 1 is shown in FIG. 2 and the same objects are again shown with reference numerals 1, 2, 3, 4, 5, 6, 7, and 10 as in FIG. 1. However, in contrast to FIG. 1, the trench structures are formed as particularly deep trench structures, and extend deep into lightly n-doped layer 2. In particular the area between the two trench structures 4 is now situated over a large part of the thickness of lightly n-doped layer 2 between trench structures 4, whereby the influence of trench structures 4 and in particular superficial layer 10 having increased surface recombination velocity is distinctly intensified. In the case of such a structure according to FIG. 2, even lesser increases of the surface recombination velocity will thus also have a lasting effect on the switching-off behavior of the diode.

In the structure according to FIG. 1, the trench structures typically have a depth which is less than 20% of the thickness of lightly n-doped layer 2. In trench structures 4 according to FIG. 2, the depth of the trench structures is typically greater than 20% of the thickness of lightly n-doped layer 2 and may be formed in such a way that they almost reach heavily n-doped layer 1. It would be considered to be the maximum value here if the depth of trench structures 4 were 98% of the thickness of lightly n-doped layer 2.

The influence of the different surface recombination velocities and the different configurations of the trench structures is shown in FIG. 6. The current flow during the switching over of a voltage in the forward direction to a voltage in the blocking direction of the diode is shown for a selected shutdown procedure in FIG. 6. The current flow through a diode according to FIG. 1 is shown in curve 61, in which no elevation of the surface recombination velocity has taken place in the area of trench structures 4. This is thus a conventional PIN diode.

In curve 62, a diode according to FIG. 1 having a surface recombination velocity S=100000 cm/sec is shown. As is apparent, the total current is less and a complete blocking effect, i.e., no further current flow in the blocking direction, is also achieved significantly more rapidly with respect to time. In curve 63, a diode according to FIG. 2 having a surface recombination velocity S=1000 cm/sec is shown. While it takes approximately 0.2 psec in curve 61 until current no longer flows and a maximum current of approximately 350 A flows overall in the blocking direction, in curve 62, current no longer flows in the blocking direction already at approximately 0.1 psec and overall a reverse current of 200 A is not exceeded. In the system of FIG. 2, a current is already no longer present in the blocking direction after less than approximately 0.1 psec and a peak current in the reverse direction of 150 A is not exceeded. These curves thus clearly indicate the influence of an increase of the surface recombination velocity or the configuration having deepened trench structures according to FIG. 2.

The various properties of the diodes in silicon technology are compared to a TMPS diode according to U.S. Pat. No. 9,006,858 B2 for the selected shutdown procedure by way of example in Table 1. Both parameters for a static operation and also dynamic parameters, i.e., in the case of a switchover mode from forward direction into blocking direction are listed. Breakdown voltage BV, i.e., the voltage from which the component breaks down in the blocking direction, reverse current IR, i.e., the current which flows statically upon application of a blocking voltage, and forward voltage UF, i.e., the voltage drop in the case of a current flow in the forward direction, which is a measure of the losses of the diode in the case of a current flow in the forward direction, are compared. With respect to the dynamic parameters, switching time trr, i.e., the time until the current flow in the blocking direction has reached the value 0 again (see FIG. 6), integrated charge Qrr achieved in this time (i.e., integral over the curves according to FIG. 6), and maximum current Irrm occurring in the blocking direction (see maximum value of curves 61, 62, 63) are listed.

| para- | require- | | | FIG. 1 | FIG. 1 | FIG. 2 |
|---|---|---|---|---|---|---|
| meter | ment | unit | TMPS | S = 0 | S = 100,000 | S = 1000 |
| BV | at 10 mA | V | 620 | 561 | 562 | 616 |
| IR | at 300 V | μA | 0.1 | 0.1 | 38 | 6.3 |
| UF | at 100 A | V | 0.93 | 0.94 | 0.97 | 1.0 |
| trr | | μsec | 0.1 | 0.195 | 0.11 | 0.08 |
| Qrr | | μAsec | 11 | 40 | 13 | 6.8 |
| Irrm | | A | 190 | 362 | 193 | 142 |

In the diode according to FIG. 1, breakthrough voltage BV is independent in very broad limits from surface recombination velocity S, however, reverse current IR increases with parameter S. Forward voltage UF also increases—at least slightly—with increasing S. In contrast, switching time trr, storage charge Qrr, and reverse current peak Irrm advantageously decrease strongly with increasing surface recombination velocity S.

The diode according to FIG. 2 is more sensitive with respect to surface recombination velocity S than the diode according to FIG. 1. The forward voltages or the reverse currents, respectively, are excessively high at S=100,000 cm/s. At S=1000 cm/s, forward voltage UF is only slightly increased, in contrast, switching time trr, storage charge Qrr, and reverse current peak Irrm are minimal.

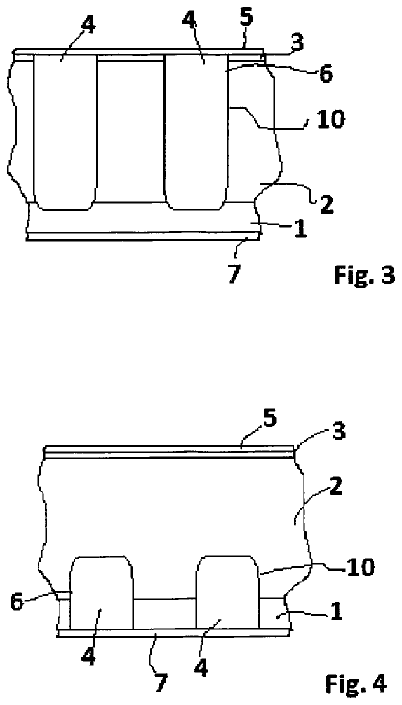

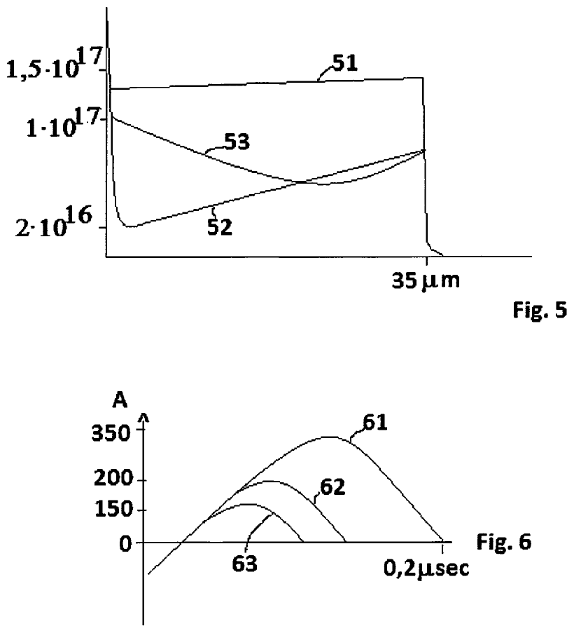

In FIG. 5, the charge carrier concentration is shown in relation to the depth of n-doped layer 2 for different diodes up to the depth of 35 μm for lightly n-doped layer 2. Curve 51 shows a structure according to FIG. 1 having a surface recombination velocity S=0 cm/sec and curve 52 shows a diode according to FIG. 1 having a surface recombination velocity S=100,000 cm/sec. The relationships in a diode according to FIG. 2 having a surface recombination velocity of S=1000 cm/sec are shown by curve 53. As may be inferred from curve 51, in a conventional PIN diode, the N-area is more or less uniformly flooded with charge carriers in the case of a current flow in the forward direction. In a diode according to FIG. 1 having a strongly increased surface recombination velocity, the charge carrier density decreases strongly in the area of the anode, and then increases continuously again up to the cathode. In a diode having a deep trench structure according to FIG. 2, a significant reduction of the charge carrier density is also visible in the area of the anode, which increases again in a curve profile toward the cathode. In the case of a charge carrier profile according to curves 53 and 52, a particularly soft switching behavior of the diode results upon shutdown while particularly abrupt switching behavior occurs in curve 51. During the dissipation of storage charge Qrr of the electron-hole plasma, the holes flow out of the electron-hole plasma to metallization 5 and the electrons flow to metallization 7 as a result of the now more negative potential at metallization 5 (voltage repolarized from transmission direction into blocking direction). A plasma-free space thus results in lightly n-doped layer 2 between p-doped layer 3 and the plasma hill, which has not yet entirely disappeared, in which the resulting electrical field of the blocking voltage propagates. To avoid an abrupt break down of the current, it is advantageous if a part of the plasma hill may remain in existence a long duration and only completely disappears after absorption of the applied blocking voltage. For example, it is advantageous if the plasma in the lightly n-doped area may be maintained for a long duration in the vicinity of heavily n-doped area 1. This may be achieved by charge carrier distributions as shown at 52 and 53 in FIG. 3.

Still another exemplary embodiment of the present invention according to a semiconductor system is shown in FIG. 3. The same subjects as in FIG. 1 or FIG. 2 are described again with reference numerals 1, 2, 3, 4, 5, 6, 7, and 10. In contrast to FIGS. 1 and 2, however, trench structure 4 is formed in a depth which exceeds the thickness of lightly n-doped layer 2. Trench structures 2 thus extend completely through lightly n-doped layer 2 and reach up to heavily n-doped layer 1. The individual PIN diodes are thus largely decoupled from one another by trench structures 10 located in between.

Another exemplary embodiment of the semiconductor system according to the present invention is shown in FIG. 4. The same objects as in FIG. 1 or 2 are again identified with reference numerals 1, 2, 3, 4, 5, 6, 7, and 10. However, in contrast to FIG. 1 or 2, the trench structure is not introduced proceeding from the upper side through p-doped layer 3 into lightly n-doped layer 2, but rather proceeding from the lower side, i.e., through heavily n-doped layer 1. The lifetime of the charge carriers in lightly n-doped area 2 is also influenced by the increased surface recombination velocity in the area of trenches 4 in this specific embodiment. The structure according to FIG. 4 may be particularly advantageous if a lightly n-doped layer 2 is epitaxially deposited on p-doped substrate 3, and in the upper side of which a heavily n-doped layer 3 is implanted or diffused, through which the trenches extend from the upper side into n-doped area 2.

1-9. (canceled)

10. A semiconductor system, comprising:
a PIN diode including a heavily n-doped layer, a lightly n-doped layer situated on the heavily n-doped layer, and a p-doped layer situated on the lightly n-doped layer, wherein the p-doped layer forms an ohmic contact with a first metallization and the heavily n-doped layer forms an ohmic contact with a second metallization, and wherein during operation in the forward direction, a high injection takes place in which the lightly n-doped layer is flooded with charge carriers;
wherein at least two trench structures are introduced into the lightly n-doped layer, the trench structures including a dielectric layer on a surface in contact with the n-doped surface, and the surface of the lightly n-doped layer in contact with the dielectric layer having an increased surface recombination velocity.

11. The semiconductor system of claim 10, wherein the surface of the lightly n-doped layer in contact with the dielectric layer has an increased surface recombination velocity only in a portion of the trench structure.

12. The semiconductor system of claim 10, wherein the ratio of width of the trench structures to the distance of the trench structures is in a range between 0.1 to 10.

13. The semiconductor system of claim 10, wherein the depth of the trench structures is between 2% and 20% of the thickness of the lightly n-doped layer.

14. The semiconductor system of claim 10, wherein the depth of the trench structures is between 20% and 98% of the thickness of the lightly n-doped layer.

15. The semiconductor system of claim 10, wherein the depth of the trench structures exceeds the thickness of the lightly n-doped layer.

16. The semiconductor system of claim 10, wherein the trench structures are introduced through the p-doped layer into the lightly n-doped layer or are introduced through the heavily n-doped layer into the lightly n-doped layer.

17. The semiconductor system of claim 10, wherein the heavy n-doping is formed by a substrate, the lightly n-doped layer is formed by an epitaxy layer, and the p-doped layer is formed by an implantation into the epitaxy layer.

18. The semiconductor system of claim 10, wherein the doping type p is exchanged with n and n is exchanged with p.

19. The semiconductor system of claim 10, wherein the surface of the lightly n-doped layer in contact with the dielectric layer has an increased surface recombination velocity only in an area of a base of the trench structure.
